(19) United States
(12) Patent Application Publication
(10) Pub. No.: US 2025/0380549 A1
(43) Pub. Date: Dec. 11, 2025

(54) Display Device

(71) Applicant: LG Display Co., Ltd., Seoul (KR)

(72) Inventors: Myeong Gu Kim, Paju-si (KR); Dong Kwan Hyun, Paju-si (KR); Won Sub So, Paju-si (KR); Hyoung Sun Park, Paju-si (KR)

(21) Appl. No.: 19/089,462

(22) Filed: Mar. 25, 2025

(30) Foreign Application Priority Data
Jun. 11, 2024 (KR) 10-2024-0075409

(51) Int. Cl. H10H 29/39; H10H 29/32; H10H 29/37; H10H 29/41; H10H 29/49; H10H 29/80; H10H 29/855

(52) U.S. Cl. CPC H10H 29/39; H10H 29/32; H10H 29/41; H10H 29/37; H10H 29/49; H10H 29/8552; H10H 29/882

(57) ABSTRACT

A display device includes a substrate; one or more buffer layers disposed on the substrate; an adhesive layer disposed on the buffer layer; a pixel driving circuit disposed on the adhesive layer; a protective layer which is disposed on the adhesive layer and of which a part is disposed on the pixel driving circuit; and a plurality of light-emitting elements electrically connected to the pixel driving circuit.

### CROSS-REFERENCE TO RELATED APPLICATION

This application claims priority to and the benefit of Republic of Korea Patent Application No. 10-2024-0075409, filed on Jun. 11, 2024, which is hereby incorporated by reference in its entirety.

### BACKGROUND

### 1. Field of Technology

The present specification relates to a display device.

### 2. Discussion of Related Art

Display devices are applied to various electronic devices such as televisions (TVs), mobile phones, notebooks, tablets, etc. Examples of a display device include an organic light-emitting diode (OLED) display device that emits light by itself, a liquid crystal display (LCD) that requires a separate light source, etc.

Recently, display devices including a light-emitting diode (LED) have been attracting attention as next-generation display devices. Since a light-emitting element is formed of an inorganic material rather than an organic material, the display device including LEDs has a faster turn-on speed, better luminous efficiency, and higher luminance images than an LCD or OLED display device.

### SUMMARY

One embodiment of the present specification is directed to providing a display device with improved quality by improving flatness on a pixel driving circuit and increasing a transfer rate of a plurality of light-emitting elements.

Objects of the present specification are not limited to the above-described objects, and other objects that are not mentioned will be able to be clearly understood by those skilled in the art based on the following description.

According to embodiments of the present specification, there is provided a display device in which a part of an overcoating layer is disposed on a pixel driving circuit and which includes a plurality of light-emitting elements disposed on the overcoating layer and electrically connected to the pixel driving circuit.

Detailed matters of other embodiments are included in the detailed description and accompanying drawings.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is an exploded perspective view of a display device according to an embodiment of the present specification;

FIG. 2 is a plan view of the display device according to an embodiment of the present specification;

FIG. 3 is an enlarged view of the display device according to an embodiment of the present specification;

FIG. 4A is a view illustrating a circuit structure according to an embodiment of the present specification;

FIG. 4B is an enlarged plan view of an area including one pixel according to an embodiment of the present specification;

FIG. 5 is a plan view of the display device according to an embodiment of the present specification;

FIG. 6 is a cross-sectional view of the display device according to an embodiment of the present specification;

FIG. 7 is a cross-sectional view of the display device according to an embodiment of the present specification;

FIG. 8 is a cross-sectional view of a display device according to another embodiment of the present specification;

FIG. 9 is an enlarged cross-sectional view of portion P in FIG. 8 according to one embodiment of the present specification;

FIG. 10 is a plan view of the display device according to another embodiment of the present specification; and

FIGS. 11 to 14 are views illustrating apparatuses to which the display device according to embodiments of the present specification is applied.

### DETAILED DESCRIPTION

Advantages and features of the present specification and methods for achieving them will become clear with reference to embodiments described below in detail in conjunction with the accompanying drawings. However, the present specification is not limited to embodiments disclosed below but will be implemented in various different forms, and these embodiments are merely provided to make the disclosure of the present specification complete and fully inform those skilled in the art to which the present specification pertains of the scope of the present specification.

Since shapes, sizes, ratios, angles, numbers, and the like disclosed in the drawings for describing the embodiments of the present specification are illustrative, the present specification is not limited to the illustrated items. The same reference number denotes the same components throughout the specification. In addition, in describing the present specification, when it is determined that the detailed description of a related known technology may unnecessarily obscure the gist of the present specification, the detailed description thereof will be omitted. When “comprise,” “have,” “include,” and the like described herein are used, other parts may be added unless “only” is used. When a component is expressed in the singular form, it includes a case in which the component is provided as a plurality of components unless specifically stated otherwise.

In construing a component, the component is construed as including a margin of error even when there is no separate explicit description related to the margin of error.

When a positional relationship is described, for example, when the positional relationship between two parts is described using “on,” “above,” “under,” “next to,” or the like, one or more other parts may be located between the two parts, for example, unless “immediately,” “directly,” or “close to” is used.

When a temporal relationship is described, when the temporal relationship is described using “after,” “subsequently,” “then,” “before,” or the like, it may also include a non-consecutive case unless “immediately” or “directly” is used.

Although a first, a second, and the like are used to describe various components, these components are not limited by these terms. These terms are only used to distinguish one component from another component. Therefore, a first component described below may be a second component within the technical spirit of the present specification.

In the description of the components of the present specification, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between the components that may be connected, coupled, joined, or attached indirectly unless stated specifically otherwise.

When a component or a layer is described as “coming into contact with” or “overlapping” another component or layer, the component or the layer may come into direct contact with or directly overlap another component or layer, but it should be understood that still another component may be interposed between the components that may come into indirect contact with and indirectly overlap each other unless specifically stated otherwise.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, various technological interworking and driving are made possible, and the embodiments may be implemented independently of each other or implemented together in an associated relationship.

Hereinafter, various embodiments of the present specification will be described in detail with reference to the accompanying drawings.

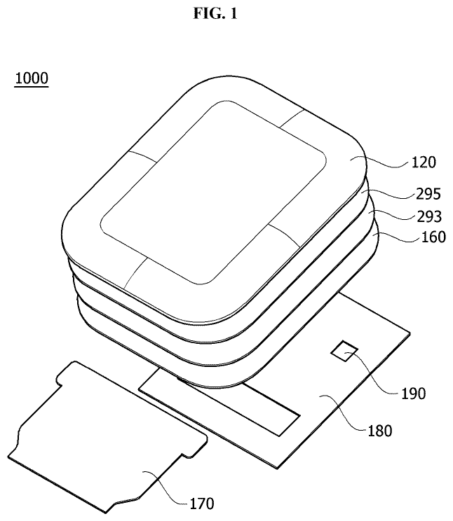

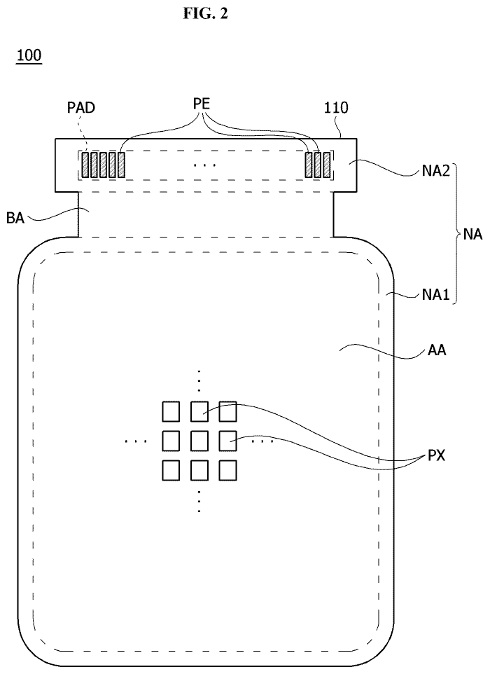

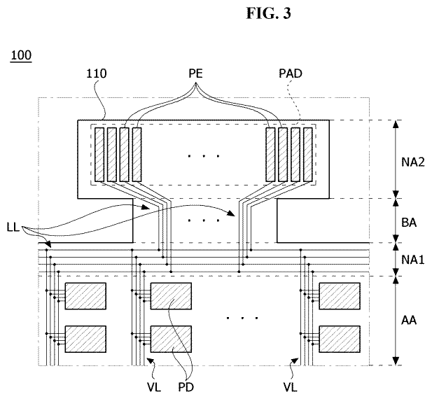

FIG. 1 is a perspective view illustrating a display device according to an embodiment of the present specification. FIG. 2 is a plan view of the display device according to an embodiment of the present specification. FIG. 3 is an enlarged view of the display device according to an embodiment of the present specification.

Referring to FIGS. 1 to 3, a display device 1000 according to the embodiment of the present specification may include a display panel 100, a polarization layer 293, an adhesive layer 295, a cover member 120, a support substrate 160, a flexible circuit board 170, and a printed circuit board 180.

For example, the display device 1000 may include a substrate 110. The substrate 110 may be a member that supports other components of the display device 1000. The substrate 110 may be formed of an insulation material. For example, the substrate 110 may be formed of glass, a resin, etc. In addition, the substrate 110 may be formed of a flexible material. For example, the substrate 110 may be formed of a flexible plastic material, such as polyimide (PI). However, the embodiments of the present specification are not limited thereto.

The display panel 100 may implement information, video, and/or image provided to a user. For example, the display panel 100 may include an active area AA and a non-active area NA. For example, the substrate 110 may include the active area AA and the non-active area NA. Descriptions of the active area AA and the non-active area NA are not limited to the substrate 110, but descriptions thereof may be made with respect to the entirety of the display device 1000.

The active area AA may be an area on which an image is displayed. The active area AA may include a plurality of pixels PX. Each of the plurality of pixels PX may be formed of a plurality of sub-pixels. A plurality of light-emitting elements may be disposed in each of the plurality of sub-pixels. A plurality of light-emitting elements may be configured differently according to the type of the display device 1000. For example, when the display device 1000 is an inorganic light-emitting display device, the light-emitting element may be a light-emitting diode (LED), a micro-LED, or a mini-LED, but the embodiments of the present specification are not limited thereto.

The non-active area NA may be an area on which no image is displayed. Various lines, circuits, and the like for driving the plurality of pixels PX of the active area AA may be disposed in the non-active area NA. For example, various lines and driving circuits may be mounted on the non-active area NA, and a pad part PAD to which an integrated circuit, a printed circuit, and the like are connected may be disposed, but the embodiments of the present specification are not limited thereto.

For example, the driving circuit may be a data driving circuit and/or a gate driving circuit, but the embodiments of the present specification are not limited thereto. Lines for supplying control signals for controlling driving circuits may be disposed. For example, the control signals may include various timing signals including a clock signal, an input data enable signal, and synchronization signals, but the embodiments of the present specification are not limited thereto. The control signals may be received through the pad part PAD. For example, link lines LL for transmitting signals may be disposed in the non-active area NA. For example, driving components, such as the flexible circuit board 170 and the printed circuit board 180, may be connected to the pad part PAD.

According to the present disclosure, the non-active area NA may include a first non-active area NA1, a bending area BA, and a second non-active area NA2. For example, the first non-active area NA1 may be an area that surrounds at least a part of the active area AA. The bending area BA may be an area extending from at least one of a plurality of sides of the first non-active area NA1 and may be a bendable area. A second non-active area NA2 may be an area extending from the bending area BA and may have the pad part PAD disposed therein. For example, the bending area BA may be bent, and the remaining area of the substrate 110 not including the bending area BA may be flat. In this case, as the bending area BA is bent, the second non-active area NA2 may be located on a rear surface of the active area AA. However, the embodiments of the present specification are not limited thereto.

The active area AA of the substrate 110 or the display device 1000 may be configured in various shapes according to the design of the display device 1000. For example, the active area AA may be formed in a rectangular shape with four rounded corners, but the embodiments of the present specification are not limited thereto. As another example, the active area AA may be formed in a rectangular shape with four right-angled corners, a circular shape, etc., but the embodiments of the present specification are not limited thereto.

According to the present disclosure, a width of the second non-active area NA2 in which a plurality of pad electrodes PE are disposed may be greater than a width of the bending area BA in which only the plurality of link lines LL are disposed. In addition, a width of the active area AA in which the plurality of sub-pixels are disposed may be greater than the width of the bending area BA in which only the plurality of link lines LL are disposed. In the drawings, the width of the bending area BA is illustrated as being narrower than widths of other areas of the substrate 110, but the shape of the substrate 110 including the bending area BA is exemplary, and the embodiments of the present specification are not limited thereto.

Referring to FIG. 3, a plurality of pixel driving circuits PD may be disposed in the active area AA. The plurality of pixel driving circuits PD may be circuits for driving the light-emitting elements of the plurality of sub-pixels. Each of the plurality of pixel driving circuits PD may include a plurality of transistors including a driving transistor, a storage capacitor, and the like and supply control signals, power, and a driving current to the light-emitting elements of the plurality of sub-pixels in order to control the light-emitting operation of the plurality of light-emitting elements. For example, the pixel driving circuit PD may include a power line and a signal line for controlling on/off of light-emitting and/or light-emitting time of the light-emitting element. For example, the plurality of pixel driving circuits PD may be driving drivers manufactured using a process of manufacturing a metal-oxide-silicon field effect transistor (MOSFET) on a semiconductor substrate, but the embodiments of the present specification are not limited thereto. The driving driver may include the plurality of pixel driving circuits PD and drive the plurality of sub-pixels.

Referring to FIG. 1 again, a flexible circuit board 170 and a printed circuit board 180 may be disposed below the display panel 100. The flexible circuit board 170 and the printed circuit board 180 may be disposed at at least one edge of the display panel 100, but the embodiments of the present specification are not limited thereto. One side of the flexible circuit board 170 may be attached to the display panel 100, and the other side may be attached to the printed circuit board 180, but the embodiments of the present specification are not limited thereto. The flexible circuit board 170 may be a flexible film, but the embodiments of the present specification are not limited thereto.

The pad part PAD including the plurality of pad electrodes PE may be disposed in the second non-active area NA2. A driving component including one or more flexible circuit boards (or flexible films) 170 and the printed circuit board 180 may be attached or bonded to the pad part PAD. The plurality of pad electrodes PE of the pad part PAD may be electrically connected to one or more flexible circuit boards (or flexible films) 170, and various signals (or power) from the printed circuit board 180 and the flexible circuit board (or the flexible film) 170 may be transmitted to the plurality of pixel driving circuits PD of the active area AA.

The flexible circuit board (or the flexible film) 170 may be a film in which various components are disposed on a flexible base film. For example, a driving IC, such as a gate driver IC or a data driver IC, may be disposed on the flexible circuit board (or the flexible film) 170, but the embodiments of the present specification are not limited thereto. The driving IC may be a component for processing data and driving signals for displaying an image. The driving IC may be disposed by a method of a chip on glass (COG), a chip on film (COF), a tape carrier package (TCP), etc. according to a mounting method, but the embodiments of the present specification are not limited thereto. The flexible circuit board (or the flexible film) 170 may be attached or bonded to the plurality of pad electrodes PE through a conductive adhesive layer, but the embodiments of the present specification are not limited thereto.

The printed circuit board 180 may be a component that is electrically connected to one or more flexible circuit boards (or flexible films) 170 and supplies signals to the driving IC. The printed circuit board 180 may be disposed at one side of the flexible circuit board (or the flexible film) 170 and electrically connected to the flexible circuit board (or the flexible film) 170. Various components for supplying various signals to the driving IC may be disposed on the printed circuit board 180. For example, various components, such as a timing controller, a power supply, a memory, a processor, etc., may be disposed on the printed circuit board 180. For example, the printed circuit board 180 may include a power management integrated circuit (PMIC), but the embodiments of the present specification are not limited thereto.

The printed circuit board 180 may include at least one hole 190, but the embodiments of the present specification are not limited thereto. An internal component for detecting ambient light, temperature, and the like that may be provided to a plurality of sensors may be disposed in an area corresponding to the at least one hole 190. For example, the internal component may include an ambient light sensor (ALS), a temperature sensor, etc., but the embodiments of the present specification are not limited thereto. For example, the hole 190 may be a transmissive hole or the like, but the embodiments of the present specification are not limited thereto.

Referring to FIG. 1, the polarization layer 293 may be disposed on a display panel 100. The polarization layer 293 can prevent or reduce light generated from an external light source from entering the display panel 100 and affecting the light-emitting element and the like.

The cover member 120 may be disposed on the polarization layer 293. The cover member 120 may be a member for protecting the display panel 100. The adhesive layer 295 may be disposed between the polarization layer 293 and the cover member 120. The cover member 120 may be attached to the display panel 100 by the adhesive layer 295. The adhesive layer 295 may include an optically clear adhesive (OCA), an optically clear resin (OCR), a pressure sensitive adhesive (PSA), etc., but the embodiments of the present specification are not limited thereto.

A support substrate 160 may be disposed between the display panel 100 and the printed circuit board 180. The support substrate 160 may reinforce the rigidity of the display panel 100. The support substrate 160 may be a back plate, but the embodiments of the present specification are not limited thereto.

Referring to FIGS. 1 to 3, the plurality of link lines LL may be disposed in the non-active area NA. The plurality of link lines LL may be lines that transmit various signals from the one or more flexible circuit boards (or flexible films) 170 and the printed circuit board 180 to the active area AA. The plurality of link lines LL may extend from the plurality of pad electrodes PE of the second non-active area NA2 toward the bending area BA and the first non-active area NA1 and may be electrically connected to a plurality of driving lines VL of the active area AA. The plurality of pixel driving circuits PD may be driven by receiving signals from the one or more flexible circuit boards (or flexible films) 170 and the printed circuit board 180 through the driving lines VL of the active area AA and the link lines LL of the non-active area NA.

For example, the plurality of driving lines VL and the plurality of link lines LL may be lines for transmitting the signals output from the flexible circuit boards (or flexible films) 170 and the printed circuit board 180 to the plurality of pixel driving circuits PD. The plurality of driving lines VL may be disposed in the active area AA and electrically connected to the plurality of pixel driving circuits PD, respectively. The plurality of driving lines VL may extend from the active area AA toward the non-active area NA and may be electrically connected to the plurality of link lines LL. Accordingly, the signals output from the flexible circuit boards (or flexible films) 170 and the printed circuit board 180 may be transmitted to the plurality of pixel driving circuits PD through the plurality of link lines LL and the plurality of driving lines VL, respectively.

As the bending area BA is bent, parts of the plurality of link lines LL may also be bent. Since stress is concentrated on the bent parts of the bent link lines LL, cracks may occur in the link lines LL. Accordingly, the plurality of link lines LL may be formed of an excellent flexible conductive material to reduce cracks when the bending area BA is bent. For example, the plurality of link lines LL may be formed of an excellent flexible conductive material, such as gold (Au), silver (Ag), aluminum (Al), etc., but the embodiments of the present specification are not limited thereto. In addition, the plurality of link lines LL may be formed of one of various conductive materials used in the active area AA. For example, the plurality of link lines LL may be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present specification are not limited thereto. The plurality of link lines LL may be formed of a multilayered structure including various conductive materials. For example, the plurality of link lines LL may be formed of a triple layer structure of titanium (Ti)/aluminum (Al)/titanium (Ti), but the embodiments of the present specification are not limited thereto.

The plurality of link lines LL may be formed in various shapes to reduce stress. At least some of the plurality of link lines LL disposed on the bending area BA may extend in the same direction as an extension direction of the bending area BA or extend in a different direction from the extension direction of the bending area BA to reduce stress. For example, when the bending area BA extends in one direction from the first non-active area NA1 to the second non-active area NA2, at least some of the link lines LL disposed on the bending area BA may extend in a direction oblique to the one direction. For another example, the at least some of the plurality of link lines LL may be formed as patterns of various shapes. For example, the at least some of the plurality of link lines LL disposed on the bending area BA may have a shape in which a conductive pattern having at least one of a diamond shape, a rhombus shape, a trapezoidal wave shape, a triangular wave shape, a sawtooth wave shape, a sine wave shape, a circular shape, and an omega ((2) shape is repeatedly disposed, but the embodiments of the present specification are not limited thereto. Accordingly, to minimize the stress concentrated on the plurality of link lines LL and cracks caused by the stress, the shape of the plurality of link lines LL may be formed in various shapes including the above shapes, but the embodiments of the present specification are not limited thereto.

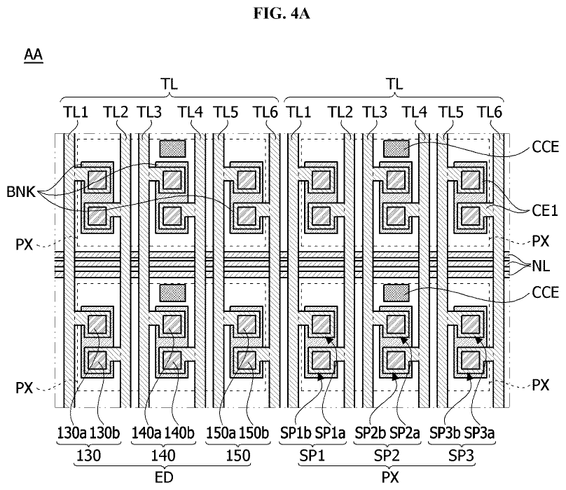

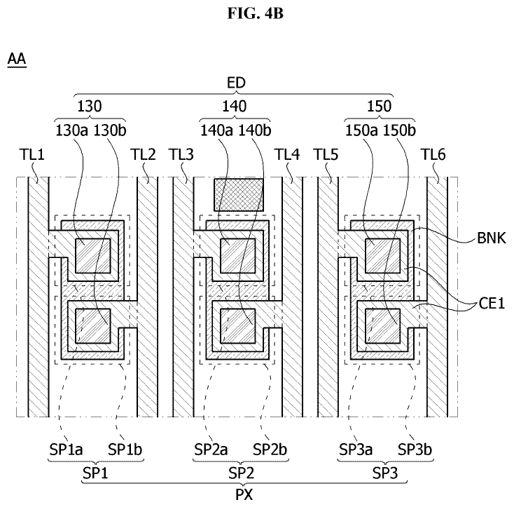

FIGS. 4A to 5 are plan views of the display device according to an embodiment of the present specification. For example, FIG. 5 is an enlarged plan view of a display area including a plurality of pixels. For example, FIG. 4B is an enlarged plan view of a display area including one pixel. In FIGS. 4B and 5, a plurality of signal lines TL, a plurality of communication lines NL, a plurality of first electrodes CE1, a plurality of banks BNK, and a plurality of light-emitting elements ED are illustrated, but the embodiments of the present specification are not limited thereto. FIG. 5 is an enlarged plan view of FIG. 4A in which a plurality of second electrodes CE2 are additionally disposed.

Referring to FIGS. 4A and 4B, a plurality of pixels PX, each of which is formed of a plurality of sub-pixels, may be disposed in the active area AA. Each of the plurality of sub-pixels may include the light-emitting element ED and independently emit light. The plurality of sub-pixels may be disposed in a matrix form that is formed of a plurality of rows and a plurality of columns, but the embodiments of the present specification are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another may be a green sub-pixel, and the remaining one may be a blue sub-pixel. The types of the plurality of sub-pixels are exemplary, and the embodiments of the present specification are not limited thereto.

Each of the plurality of pixels PX may include one or more first sub-pixels SP1, one or more second sub-pixels SP2, and one or more third sub-pixels SP3. For example, one pixel PX may include one pair of first sub-pixels SP1, one pair of second sub-pixels SP2, and one pair of third sub-pixels SP3. The pair of first sub-pixels SP1 may be formed of a 1-1 sub-pixel SP1a and a 1-2 sub-pixel SP1b. The pair of second sub-pixels SP2 may be formed of a 2-1 sub-pixel SP2a and a 2-2 sub-pixel SP2b. The pair of third sub-pixels SP3 may be formed of a 3-1 sub-pixel SP3a and a 3-3 sub-pixel SP3b. For example, one pixel PX may include the 1-1 sub-pixel SP1a and the 1-2 sub-pixel SP1b, the 2-1 sub-pixel SP2a and the 2-2 sub-pixel SP2b, and the 3-1 sub-pixel SP3a and the 3-2 sub-pixel SP3b, but the embodiments of the present specification are not limited thereto.

The plurality of sub-pixels forming the one pixel PX may be arranged in various ways. For example, in one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of plurality of sub-pixels forming one pixel PX are exemplary, and the embodiments of the present specification are not limited thereto.

The plurality of signal lines TL may be disposed in an area between the plurality of sub-pixels. The plurality of signal lines TL may extend in a column direction between the plurality of sub-pixels. The plurality of signal lines TL may be lines that transmit an anode voltage from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal lines TL. For example, the first electrode CE1 may be an electrode that is electrically connected to an anode electrode 134 of the light-emitting element ED. Accordingly, the anode voltage from the signal line TL may be transmitted to the anode electrode 134 of the light-emitting element ED through the first electrode CE1.

Accordingly, the structure of the display device 1000 can be simplified using the pixel driving circuit PD in which a plurality of pixel circuits are integrated instead of forming a plurality of transistors and storage capacitors in each of the plurality of sub-pixels. In addition, since circuits disposed in each of the plurality of sub-pixels are integrated in one pixel driving circuit PD, high-efficiency, low-power driving can be made possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed at one side of the pair of first sub-pixels SP1, and the second signal line TL2 may be disposed at the other side of the pair of first sub-pixels SP1. The first signal line TL1 may be electrically connected to the first electrode CE1 of one of the pair of first sub-pixels SP1, for example, the 1-1 sub-pixel SP1a. The second signal line TL2 may be electrically connected to the first electrode CE1 of the other of the pair of first sub-pixels SP1, for example, the 1-2 sub-pixel SP1b.

The third signal line TL3 may be disposed at one side of the pair of second sub-pixels SP2, and the fourth signal line TL4 may be disposed at the other side of the pair of second sub-pixels SP2. For example, the third signal line TL3 may be disposed adjacent to the second signal line TL2. The third signal line TL3 may be electrically connected to the first electrode CE1 of one of the pair of second sub-pixels SP2, for example, the 2-1 sub-pixel SP2a. The fourth signal line TL4 may be electrically connected to the first electrode CE1 of the other of the pair of second sub-pixels SP2, for example, the 2-2 sub-pixel SP2b.

The fifth signal line TL5 may be disposed at one side of the pair of third sub-pixels SP3, and the sixth signal line TL6 may be disposed at the other side of the pair of third sub-pixels SP3. For example, the fifth signal line TL5 may be disposed adjacent to the fourth signal line TL4. The sixth signal line TL6 may be disposed adjacent to the first signal line TL1 connected to a neighboring pixel PX. The fifth signal line TL5 may be electrically connected to the first electrode CE1 of one of the pair of third sub-pixels SP3, for example, the 3-1 sub-pixel SP3a. The sixth signal line TL6 may be electrically connected to the first electrode CE1 of the other of the pair of third sub-pixels SP3, for example, the 3-2 sub-pixel SP3b.

The plurality of signal lines TL may be formed of a conductive material. For example, the plurality of signal lines TL may be formed of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the embodiments of the present specification are not limited thereto. As another example, the plurality of signal lines TL may be formed of a conductive multilayered structure. For example, the plurality of signal lines TL may be formed of a multilayered structure of titanium (Ti)/aluminum (Al)/titanium (Ti)/indium tin oxide (ITO), but the embodiments of the present specification are not limited thereto.

The plurality of communication lines NL may be disposed in an area between the plurality of pixels PX. The plurality of communication lines NL may be disposed to extend in a row direction in the area between the plurality of pixels PX. The plurality of communication lines NL may be disposed in an area between a plurality of second electrodes CE2 and may not overlap the plurality of second electrodes CE2. For example, the plurality of communication lines NL may be lines used for short-range communication, such as near field communication (NFC). The plurality of communication lines NL may serve as antennas. For example, the plurality of communication lines NL may be a plurality of connection lines, but the embodiments of the present specification are not limited thereto.

According to the present disclosure, the bank BNK may be disposed in each of the plurality of sub-pixels. The plurality of banks BNK may be structures on which the plurality of light-emitting elements ED are seated. The plurality of banks BNK may give guidance related to the locations of the plurality of light-emitting elements ED in a transfer process of transferring the plurality of light-emitting elements ED onto the display device 1000. In the transfer process of the plurality of light-emitting elements ED, the plurality of light-emitting elements ED may be transferred onto the plurality of banks BNK. The plurality of banks BNK may be bank patterns, structures, etc., but the embodiments of the present specification are not limited thereto.

A bank BNK of the first sub-pixel SP1, a bank BNK of the second sub-pixel SP2, and a bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be formed separately. Accordingly, the banks BNK of the first sub-pixel SP1, the second sub-pixel SP2, and the third sub-pixel SP3 onto which different types of light-emitting elements ED are transferred can be easily identified.

A bank BNK of the 1-1 sub-pixel SP1a and a bank BNK of the 1-2 sub-pixel SP1b may be connected and formed to be spaced apart from each other or formed separately. For example, considering the design of the transfer process requirements and the like, the bank BNK of the 1-1 sub-pixel SP1a and the bank BNK of the 1-2 sub-pixel SP1b in which the same type of light-emitting element ED is disposed may be connected and formed to be spaced apart from each other or formed separately. In addition, a bank BNK of the 2-1 sub-pixel SP2a and a bank BNK of the 2-2 sub-pixel SP2b may be connected or formed to be spaced apart from each other or formed separately. A bank BNK of the 3-1 sub-pixel SP3a and a bank BNK of the 3-2 sub-pixel SP3b may be connected or formed to be spaced apart from each other or formed separately. Accordingly, the banks BNK of the pair of the first sub-pixels SP1, the banks BNK of the pair of the second sub-pixels SP2, and the banks BNK of the pair of the third sub-pixels SP3 may be formed in various ways, and the embodiments of the present specification are not limited thereto.

For example, the plurality of banks BNK may be formed of an organic insulation material. The plurality of banks BNK may be formed of a single layer or multiple layers of an organic insulation material. For example, the plurality of banks BNK may be formed of a photoresist, polyimide (PI), or acrylic-based material, but the embodiments of the present specification are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a part of the first electrode CE1 may extend outward of the bank BNK and may be electrically connected to the signal line TL closest to the first electrode CE1. For example, a part of the first electrode CE1 of the 1-1 sub-pixel SP1a may extend to one area of the 1-1 sub-pixel SP1a and may be electrically connected to the first signal line TL1, and a part of the first electrode CE1 of the 1-2 sub-pixel SP1b may extend to the other area of the 1-2 sub-pixel SP1b and may be electrically connected to the second signal line TL2. A part of the first electrode CE1 of the 2-1 sub-pixel SP2a may extend to one area of the 2-1 sub-pixel SP2a and may be electrically connected to the third signal line TL3, and a part of the first electrode CE1 of the 2-2 sub-pixel SP2b may extend to the other area of the 2-2 sub-pixel SP2b and may be electrically connected to the fourth signal line TL4. A part of the first electrode CE1 of the 3-1 sub-pixel SP3a may extend to one area of the 3-1 sub-pixel SP3a and may be electrically connected to the fifth signal line TL5, and a part of the first electrode CE1 of the 3-2 sub-pixel SP3b may extend to the other area of the 3-2 sub-pixel SP3b and may be electrically connected to the sixth signal line TL6.

The first electrode CE1 may be electrically connected to the anode electrode 134 of the light-emitting element ED and may transmit the anode voltage from the pixel driving circuit PD to the light-emitting element ED through the signal line TL. A different voltage may be applied to the first electrode CE1 of each of the plurality of sub-pixels according to a displayed image. For example, a different voltage may be applied to the first electrode CE1 of each of the plurality of sub-pixels. Accordingly, the first electrode CE1 may be a pixel electrode, and the embodiments of the present specification are not limited thereto.

The first electrode CE1 may be formed of a conductive material. For example, the first electrodes CE1 may be formed integrally with the plurality of signal lines TL. For example, the first electrode CE1 may be formed of the same conductive material as the plurality of signal lines TL, but the embodiments of the present specification are not limited thereto. For example, the first electrode CE1 may be formed of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the embodiments of the present disclosure are not limited thereto. As another example, the first electrode CE1 may be formed of a conductive multilayered structure. For example, the plurality of first electrodes CE1 may be formed of a multilayered structure of titanium (Ti)/aluminum (Al)/titanium (Ti)/indium tin oxide (ITO), but the embodiments of the present specification are not limited thereto.

The light-emitting element ED may be disposed in each of the plurality of sub-pixels. The plurality of light-emitting elements ED may be one of an LED or a micro-LED, but the embodiments of the present disclosure are not limited thereto. The plurality of light-emitting elements ED may be disposed on the bank BNK and the first electrode CE1. The plurality of light-emitting elements ED may be disposed on the first electrode CE1 and electrically connected to the first electrode CE1. Accordingly, the light-emitting element ED may receive the anode voltage from the pixel driving circuit PD through the signal line TL and the first electrode CE1 and emit light.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another may be a green light-emitting element, and the remaining one may be a blue light-emitting element, but the embodiments of the present specification are not limited thereto. Accordingly, red light, green light, and blue light emitted from the plurality of light-emitting elements ED may be combined to implement various colors of light including white. The types of the plurality of light-emitting elements ED are exemplary, and the embodiments of the present specification are not limited thereto.

The first light-emitting element 130 may include a 1-1 light-emitting element 130a disposed in the 1-1 sub-pixel SP1a and a 1-2 light-emitting element 130b disposed in the 1-2 sub-pixel SP1b. The second light-emitting element 140 may include a 2-1 light-emitting element 140a disposed in the 2-1 sub-pixel SP2a and a 2-2 light-emitting element 140b disposed in the 2-2 sub-pixel SP2b. The third light-emitting element 150 may include a 3-1 light-emitting element 150a disposed in the 3-1 sub-pixel SP3a and a 3-2 light-emitting element 150b disposed in the 3-2 sub-pixel SP3b.

Referring to FIGS. 4A, 4B, and 5 together, the second electrode CE2 may be disposed on each of the plurality of sub-pixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to a cathode electrode 135 of the light-emitting element ED to transmit a cathode voltage from the pixel driving circuit PD to the light-emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light-emitting element ED. Accordingly, the second electrode CE2 may be a common electrode, and the embodiments of the present specification are not limited thereto.

At least some of the plurality of sub-pixels may share the second electrode CE2. At least some of the second electrodes CE2 of the plurality of sub-pixels may be electrically connected. Since the same voltage is applied to the second electrodes CE2, the second electrodes CE2 of at least some sub-pixels may be shared and used. For example, the second electrodes CE2 of at least some pixels PX among the plurality of pixels PX disposed in the same row may be connected. For example, one second electrode CE2 may be disposed in each of the plurality of pixels PX. One second electrode CE2 may be disposed per n sub-pixels.

For example, some of the second electrodes CE2 of the plurality of sub-pixels may be disposed to be spaced apart from each other or disposed separately. For example, second electrodes CE2 connected to pixels PX in an nth row and second electrodes CE2 connected to pixels PX in an (n+1)th row may be disposed to be spaced apart from each other or disposed separately. For example, the plurality of second electrodes CE2 may be disposed to be spaced apart from each other with the plurality of communication lines NL extending in a row direction interposed therebetween. Accordingly, the number of plurality of sub-pixels may be more than the number of plurality of second electrodes CE2. As another example, all of the second electrodes CE2 of the plurality of sub-pixels may be connected so that only one second electrode CE2 may be disposed on the substrate 110, and the embodiments of the present specification are not limited thereto.

The plurality of second electrodes CE2 may be formed of a transparent conductive material, but the embodiments of the present disclosure are not limited thereto. The plurality of second electrodes CE2 may be formed of a transparent conductive material so that light emitted from the light-emitting element ED may emit upward with respect to the second electrodes CE2. For example, the second electrode CE2 may be formed of a transparent conductive material, such as indium tin oxide (ITO), indium zinc oxide (IZO), indium gallium zinc oxide (IGZO), etc., but the embodiments of the present specification are not limited thereto.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrode CE2.

For example, when a micro-LED is used as the light-emitting element ED, the display device 1000 may be manufactured by forming a plurality of micro-LEDs on a wafer and transferring the micro-LEDs onto the substrate 110 of the display device 1000. During the process of transferring the plurality of light-emitting elements ED having a micro size from the wafer onto the substrate 110, various types of defects may occur. For example, a non-transfer defect in which the light-emitting element ED is not transferred may occur in some sub-pixels, and a defect in which the light-emitting element ED is transferred out of a correct location due to an alignment error may occur in other sub-pixels. In addition, the transfer process may be performed normally, but the transferred light-emitting element ED may be defective. Accordingly, in consideration of defects during the transfer process of the plurality of light-emitting elements ED, the plurality of light-emitting elements ED of the same type may be transferred onto one sub-pixel. A lighting test of the plurality of light-emitting elements ED may be performed, and only one light-emitting element ED that is ultimately determined to be normal may be used.

For example, both the 1-1 light-emitting element 130a and the 1-2 light-emitting element 130b may be transferred onto one pixel PX, and whether the 1-1 light-emitting element 130a and the 1-2 light-emitting element 130b are defective may be tested. When it is determined that both the 1-1 light-emitting element 130a and the 1-2 light-emitting element 130b are normal, only the 1-1 light-emitting element 130a may be used, and the 1-2 light-emitting element 130b may not be used. As another example, when it is determined that only the 1-2 light-emitting element 130b among the 1-1 light-emitting element 130a and the 1-2 light-emitting element 130b is normal, the 1-1 light-emitting element 130a is not used, and only the 1-2 light-emitting element 130b may be used. Accordingly, even when the plurality of light-emitting elements ED of the same type are transferred onto one pixel PX, only one light-emitting element ED may be eventually used.

Accordingly, one of the pair of light-emitting elements ED may be a main (or primary) light-emitting element ED, and the other may be a redundancy light-emitting element ED. The redundancy light-emitting element ED may be a spare light-emitting element ED transferred in preparation of a defect of the main light-emitting element ED. When the main light-emitting element ED is defective, the defective main light-emitting element ED may be replaced with the redundancy light-emitting element ED and used. Accordingly, by transferring both the main light-emitting element ED and the redundancy light-emitting element ED onto one pixel PX, it is possible to minimize or at least reduce the degradation of display quality due to the defects of the main light-emitting element ED and the redundancy light-emitting element ED.

For example, the 1-1 light-emitting element 130a, the 2-1 light-emitting element 140a, and the 3-1 light-emitting element 150a that are transferred onto one pixel PX may be used as the main light-emitting element ED, and the 1-2 light-emitting element 130b, the 2-2 light-emitting element 140b, and the 3-2 light-emitting element 150b may be used as the redundancy light-emitting element ED.

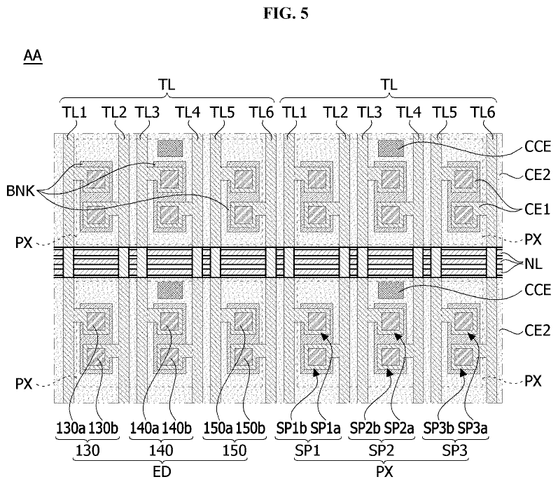

FIG. 6 is a cross-sectional view of the display device according to the embodiment of the present disclosure. For example, FIG. 6 is a cross-sectional view of the active area AA, the first non-active area NA1, the bending area BA, and the second non-active area NA2.

Referring to FIG. 6, a first buffer layer 111a and a second buffer layer 111b may be disposed in the remaining area of the substrate 110 not including the bending area BA.

The first buffer layer 111a and the second buffer layer 111b may be disposed in the active area AA, the first non-active area NA1, and the second non-active area NA2. The first buffer layer 111a and the second buffer layer 111b may reduce the penetration of moisture or impurities into the substrate 110. The first buffer layer 111a and the second buffer layer 111b may be formed of an inorganic insulation material. For example, the first buffer layer 111a and the second buffer layer 111b may be formed of a single layer or multiple layers of silicon oxide (SiOx) or silicon nitride (SiNx), but the embodiments of the present specification are not limited thereto.

For example, parts of the first buffer layer 111a and the second buffer layer 111b on the bending area BA may be removed. An upper surface of the substrate 110 located in the bending area BA may be exposed with respect to the first buffer layer 111a and the second buffer layer 111b. By removing the first buffer layer 111a and the second buffer layer 111b, which are formed of an inorganic insulation material, from the bending area BA, it is possible to minimize or at least reduce cracks in the first buffer layer 111a and the second buffer layer 111b, which may occur during bending.

A plurality of alignment keys MK may be disposed between the first buffer layer 111a and the second buffer layer 111b. The plurality of alignment keys MK may be formed to identify the location of the pixel driving circuit PD during the manufacturing process of the display device 1000. For example, the plurality of alignment keys MK may be formed to align the location of the pixel driving circuit PD transferred onto the adhesive layer 112. In another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, at least a part of the adhesive layer 112 may be removed from the non-active area NA including the bending area BA. For example, the adhesive layer 112 may be formed of one of an adhesive polymer, an epoxy resin, a UV-curable resin, a polyimide-based material, an acrylate-based material, a urethane-based material, and a polydimethylsiloxane (PDMS), but the embodiments of the present specification are not limited thereto.

The pixel driving circuit PD may be disposed on the adhesive layer 112 in the active area AA. When the pixel driving circuit PD is implemented as a driving driver, the driving driver may be mounted on the adhesive layer 112 by a transfer process, but the embodiments of the present specification are not limited thereto.

A first protective layer 113a and a second protective layer 113b may be disposed on the adhesive layer 112 and the pixel driving circuit PD. The first protective layer 113a and the second protective layer 113b may be disposed to surround side surfaces of the pixel driving circuit PD, but the embodiments of the present disclosure are not limited thereto. For example, a part of the second protective layer 113b may be disposed to cover at least a part of an upper surface of the pixel driving circuit PD. In this case, a part of the pixel driving circuit PD covered by the second protective layer 113b may be an edge of the upper surface of the pixel driving circuit PD. According to one embodiment of the present disclosure, parts of a third protective layer and a plurality of organic insulation layers that are disposed above the pixel driving circuit PD may also protrude due to a part of the second protective layer 113b located at the edge of the upper surface of the pixel driving circuit PD. Accordingly, heights of some of the plurality of light-emitting elements 130, 140, and 150 may be increased to an upper end of the protruding organic insulation layer. In this case, when the plurality of light-emitting elements 130, 140, and 150 of the present disclosure are micro-LED, the sizes thereof may vary according to each color. More specifically, in the case of the micro-LED, the sizes of a green chip and a blue chip may be smaller than that of a red chip. According to one embodiment of the present disclosure, by arranging areas of lower layers protruding from lower ends of the relatively small light-emitting elements, it is possible to eliminate steps in which uppermost ends of the plurality of light-emitting elements have different heights and thereby secure a high degree of flatness. Accordingly, it is possible to solve the non-transfer problem of the light-emitting element having a relatively low height and thereby increase a transfer rate.

A positional relationship of components from the pixel driving circuit PD to the light-emitting elements 130, 140, and 150 will be described in more detail below.

At least one of the first protective layer 113a and the second protective layer 113b that are disposed on the bending area BA may be omitted. For example, the first protective layer 113a may be entirely disposed in the active area AA and the non-active area NA, and a part of the second protective layer 113b may be disposed in the active area AA, the first non-active area NA1, and the second non-active area NA2. For example, a part of the second protective layer 113b in the bending area BA may be removed. However, the embodiments of the present specification are not limited thereto.

The first protective layer 113a and the second protective layer 113b may be formed of an organic insulation material, but the embodiments of the present specification are not limited thereto. For example, the first protective layer 113a and the second protective layer 113b may be formed of a photoresist, polyimide (PI), or photo acryl-based material, but the embodiments of the present specification are not limited thereto. For example, the first protective layer 113a and the second protective layer 113b may be an overcoating layer or an insulating layer, but the embodiments of the present specification are not limited thereto.

According to the present disclosure, a plurality of first connection lines 121 may be disposed on the second protective layer 113b in the active area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present specification are not limited thereto.

For example, the plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit the voltage output from the pixel driving circuit PD to the first electrode CE1 or the second electrode CE2.

For example, the third protective layer 114 may be disposed on the second protective layer 113b. The third protective layer 114 may be disposed across the active area AA and the non-active area NA. In the bending area BA, the third protective layer 114 may cover side surfaces of the second protective layer 113b and an upper surface of the first protective layer 113a. The third protective layer 114 may be formed of an organic insulation material. For example, the third protective layer 114 may be formed of a photoresist, polyimide (PI), or photo acryl-based material, but the embodiments of the present specification are not limited thereto. For example, the first protective layer 113a, the second protective layer 113b, and the third protective layer 114 may be formed of the same material. The embodiments of the present specification are not limited thereto.

The plurality of 1-2 connection lines 121b may be disposed on the third protective layer 114. The plurality of 1-2 connection lines 121b may be connected to the pixel driving circuit PD or directly connected to components. For example, a part of the 1-2 connection line 121b may be directly connected to the pixel driving circuit PD through a contact hole of the third protective layer 114. Another part of the 1-2 connection line 121b may be electrically connected to the 1-1 connection line 121a through a contact hole of the third protective layer 114. However, the embodiments of the present specification are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be disposed across the active area AA and the non-active area NA, but the embodiments of the present specification are not limited thereto. The first insulating layer 115a may be formed of an organic insulation material, but the embodiments of the present specification are not limited thereto. For example, the first insulating layer 115a may be formed of a photoresist, polyimide (PI), or photo acryl-based material, but the embodiments of the present specification are not limited thereto.

The plurality of 1-3 connection lines 121c may be disposed on the first insulating layer 115a. The plurality of 1-3 connection lines 121c may be electrically connected to the plurality of 1-2 connection lines 121b. For example, the 1-3 connection line 121c may be electrically connected to the 1-2 connection line 121b through a contact hole of the first insulating layer 115a.

A second insulating layer 115b may be disposed on the plurality of the 1-3 connection lines 121c. The second insulating layer 115b may be disposed in the remaining area not including the bending area BA, but the embodiments of the present specification are not limited thereto. The second insulating layer 115b may be disposed in the active area AA, the first non-active area NA1, and the second non-active area NA2, but the embodiments of the present specification are not limited thereto. For example, a part of the second insulating layer 115b disposed in the bending area BA may be removed. The second insulating layer 115b may be formed of an organic insulation material, but the embodiments of the present specification are not limited thereto. For example, the second insulating layer 115b may be formed of a photoresist, polyimide (PI), or photo acryl-based material, but the embodiments of the present specification are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection line 121d may be electrically connected to the 1-3 connection line 121c through a contact hole of the second insulating layer 115b.

According to the present disclosure, a plurality of second connection lines 122 may be disposed on the second protective layer 113b in the non-active area NA. The plurality of second connection lines 122 may be lines for transmitting signals transmitted from the flexible circuit board (or the flexible film) 150 and the printed circuit board 160 (see FIG. 1) to the pad part PAD to the pixel driving circuit PD of the active area AA. For example, the plurality of second connection lines 122 may be electrically connected to the plurality of pad electrodes PE to receive signals from the flexible circuit board (or the flexible film) 150 and the printed circuit board.

For example, the plurality of second connection lines 122 may extend from the pad part PAD toward the active area AA to transmit signals to lines of the active area AA. In this case, the plurality of second connection lines 122 may serve as link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-active area NA2 to the bending area BA and the first non-active area NA1. The plurality of 2-1 connection lines 122a may transmit the signals transmitted from the flexible circuit board (or the flexible film) 150 and the printed circuit board to the pad part PAD to the pixel driving circuit PD of the active area AA.

The plurality of 2-2 connection lines 122b may be disposed on the third protective layer 114. The plurality of 2-2 connection lines 122b may be disposed in the second non-active area NA2. The 2-2 connection line 122b may be electrically connected to the 2-1 connection line 122a through a contact hole of the third protective layer 114. Accordingly, the signals from the flexible circuit board (or the flexible film) 150 and the printed circuit board may be transmitted to the 2-1 connection line 122a through the 2-2 connection line 122b.

The 2-3 connection line 122c may be disposed on the first insulating layer 115a. The 2-3 connection line 122c may be disposed in the second non-active area NA2. The 2-3 connection line 122c may be electrically connected to the 2-2 connection line 122b through a contact hole of the first insulating layer 115a. Accordingly, the signals from the flexible circuit board (or the flexible film) 150 and the printed circuit board may be transmitted to the 2-1 connection line 122a through the 2-3 connection line 122c and the 2-2 connection line 122b.

The 2-4 connection line 122d may be disposed on the second insulating layer 115b. The 2-4 connection line 122d may be disposed in the second non-active area NA2. The 2-4 connection line 122d may be electrically connected to the 2-3 connection line 122c through a contact hole of the second insulating layer 115b. Accordingly, the signals from the flexible film FF and the printed circuit board may be transmitted to the 2-1 connection line 1202a through the 2-4 connection line 122d, the 2-3 connection line 122c, and the 2-2 connection line 122b.

The plurality of first connection lines 121 and the plurality of second connection lines 122 may be formed of an excellent flexible conductive material or one of various conductive materials used in the active area AA. For example, the second connection line 122 of which a part is disposed in the bending area BA may be formed of an excellent flexible conductive material, such as gold (Au), silver (Ag), aluminum (Al), etc., but the embodiments of the present specification are not limited thereto. As another example, the plurality of first connection lines 121 and the plurality of second connection lines 122 may be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present specification are not limited thereto.

The third insulating layer 115c may be disposed on the plurality of first connection lines 121 and the plurality of second connection lines 122. The third insulating layer 115c may be disposed in the remaining area not including the bending area BA, but the embodiments of the present specification are not limited thereto. The third insulating layer 115c may be disposed in the active area AA, the first non-active area NA1, and the second non-active area NA2. A part of the third insulating layer 115c in the bending area BA may be removed. The third insulating layer 115c may be formed of an organic insulation material, but the embodiments of the present specification are not limited thereto. For example, the third insulating layer 115c may be formed of a photoresist, polyimide (PI), or photo acryl-based material, but the embodiments of the present specification are not limited thereto.

A plurality of banks BNK may be disposed on the third insulating layer 115c in the active area AA. The plurality of banks BNK may be disposed to overlap the plurality of sub-pixels, respectively. One or more light-emitting elements ED of the same type may be disposed on each of the plurality of banks BNK.

The plurality of signal lines TL may be disposed on the third insulating layer 115c in the active area AA. The plurality of signal lines TL may be disposed in an area between the plurality of banks BNK. For example, the plurality of signal lines TL may be disposed adjacent to one of the plurality of banks BNK.

The plurality of contact electrodes CCE may be disposed on the third insulating layer 115c in the active area AA. The plurality of contact electrodes CCE may supply cathode voltage from the pixel driving circuit PD to the second electrode CE2.

The first electrode CE1 may be disposed on the bank BNK. For example, the first electrode CE1 may be disposed to extend from an adjacent signal line TL toward an upper portion of the bank BNK. The first electrode CE1 may be disposed on an upper surface of the bank BNK and side surfaces of the bank BNK. For example, the first electrode CE1 may be disposed to extend from the signal line TL on the upper surface of the third insulating layer 115c to the side surfaces of the bank BNK and the upper surface of the bank BNK.

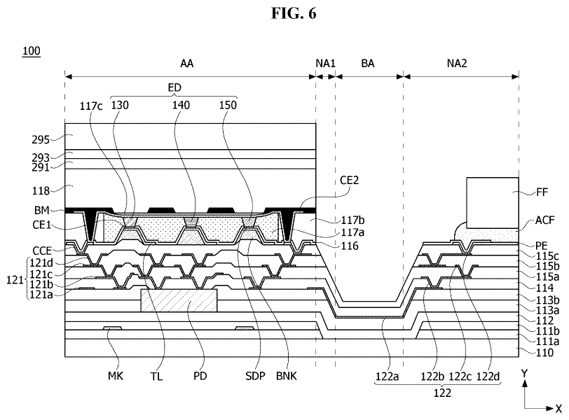

Referring to FIG. 7, the first electrode CE1 may be formed of a plurality of conductive layers. For example, the first electrode CE1 may include a first conductive layer CEla, a second conductive layer CE1b, a third conductive layer CE1c, and a fourth conductive layer CE1d, but the embodiments of the present specification are not limited thereto.

The first conductive layer CEla may be disposed on the bank BNK. The second conductive layer CElb may be disposed on the first conductive layer CEla. The third conductive layer CE1c may be disposed on the second conductive layer CE1b, and the fourth conductive layer CEld may be disposed on the third conductive layer CE1c. For example, each of the first conductive layer CEla, the second conductive layer CE1b, the third conductive layer CElc, and the fourth conductive layer CEld may be formed of titanium (Ti), molybdenum (Mo), aluminum (Al), or titanium (Ti) and indium tin oxide (ITO), but the embodiments of the present specification are not limited thereto.

According to the present disclosure, among the plurality of conductive layers forming the first electrode CE1, some of the conductive layers, which have good reflection efficiency, may be formed as an alignment key for aligning the light-emitting element ED and/or a reflector. For example, the second conductive layer CE1b among the plurality of conductive layers of the first electrode CE1 may include a reflective material. For example, the second conductive layer CE1b may include aluminum (Al), but the embodiments of the present specification are not limited thereto. Accordingly, the second conductive layer CE1b may be formed to be a reflector. In addition, due to the high reflection efficiency of the second conductive layer CE1b, the second conductive layer CElb can be easily identified in the manufacturing process, and thus the location or transfer location of the light-emitting element ED may be aligned based on the second conductive layer CE1b.

For example, to form the second conductive layer CE1b as a reflector, parts of the third conductive layer CE1c and the fourth conductive layer CEld that cover the second conductive layer CE1b may be removed or etched. For example, parts of the third conductive layer CE1c and the fourth conductive layer CEld that are disposed on the bank BNK may be removed or etched to expose an upper surface of the second conductive layer CE1b. For example, central portions and border portions (or edge portions) of the third conductive layer CE1c and the fourth conductive layer CE1d, in which a solder pattern SDP is disposed may be left, and the remaining portions not including the central and border portions may be removed. For example, the border portion (or the edge portion) of each of the third conductive layer CE1c formed of titanium (Ti) and the fourth conductive layer CE1d formed of indium tin oxide (ITO) may not be etched. Accordingly, it is possible to prevent or at least reduce other conductive layers of the first electrode CE1 from being corroded by a tetramethylammonium hydroxide (TMAH) solution used in a masking process of the first electrode CE1.

According to the present disclosure, the first conductive layer CEla and the third conductive layer CElc may include titanium (Ti) or molybdenum (Mo). The second conductive layer CE1b may include aluminum (Al). The fourth conductive layer CEld may include a transparent conductive oxide layer, such as indium tin oxide (ITO) or indium zinc oxide (IZO), which has high adhesion to the solder pattern SDP, corrosion resistance, and acid resistance. However, the embodiments of the present specification are not limited thereto.

The first conductive layer CEla, the second conductive layer CE1b, the third conductive layer CE1c, and the fourth conductive layer CEld may be sequentially deposited and then patterned by performing a photolithography process and an etching process, but the embodiments of the present disclosure are not limited thereto.

According to the present disclosure, the signal line TL, the contact electrode CCE, and the pad electrode PE that are disposed on the same layer as the first electrode CE1 may be formed in conductive multiple layers, but the embodiments of the present disclosure are not limited thereto. For example, the signal line TL, the contact electrode CCE, and the pad electrode PE may be formed in multiple layers of indium tin oxide (ITO)/titanium (Ti)/aluminum (Al)/titanium (Ti), but the embodiments of the present disclosure are not limited thereto.

According to the present disclosure, the solder pattern SDP may be disposed on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP, but the embodiments of the present disclosure are not limited thereto. For example, when the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. The light-emitting element ED may be bonded to the solder pattern SDP and the first electrode CE1 without a separate adhesive through eutectic bonding. For example, the solder pattern SDP may be formed of In, Sn, or an alloy thereof, but the embodiments of the present specification are not limited thereto. For example, the solder pattern SDP may be a bonding pad or the like, but the embodiments of the present specification are not limited thereto.

According to the present disclosure, a passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. The part of the passivation layer 116 covering the plurality of pad electrodes PE in the second non-active area NA2 may be removed. Since the passivation layer 116 is disposed to cover the remaining area not including the bending area BA, the plurality of pad electrodes PE, and the area in which the solder pattern SDP is disposed, it is possible to reduce the penetration of moisture or impurities into the light-emitting element ED. For example, the passivation layer 116 may be formed of a single layer or multiple layers of silicon oxide (SiOx) or silicon nitride (SiNx), but the embodiments of the present specification are not limited thereto. For example, the passivation layer 116 may be a protective layer, an insulating layer, etc., but the embodiments of the present specification are not limited thereto. For example, the passivation layer 116 may include a hole exposing the solder pattern SDP.

The light-emitting element ED may be disposed on the solder pattern SDP in each of the plurality of sub-pixels. The first light-emitting element 130 may be disposed in the first sub-pixel SP1. The second light-emitting element 140 may be disposed in the second sub-pixel SP2. The third light-emitting element 150 may be disposed in the third sub-pixel SP3.

The light-emitting element ED may be formed on a silicon wafer by a method of metal organic chemical vapor deposition (MOCVD), CVD, plasma-enhanced CVD (PECVD), molecular beam epitaxy (MBE), hydride vapor phase epitaxy (HVPE), sputtering, etc., but the embodiments of the present specification are not limited thereto.

Referring to FIG. 7, the first light-emitting element 130 may include the anode electrode 134, a first semiconductor layer 131, an active layer 132, a second semiconductor layer 133, the cathode electrode 135, and an encapsulation film 136, but the embodiments of the present specification are not limited thereto. For example, the encapsulation film 136 may not be included in the first light-emitting element 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor of group III-V, group II-VI, etc. and may be doped with an impurity (or a dopant). For example, one of the first semiconductor layer 131 and the second semiconductor layer 133 may be a semiconductor layer doped with an n-type impurity, and the other may be a semiconductor layer doped with a p-type impurity, but the embodiments of the present disclosure are not limited thereto. For example, at least one of the first semiconductor layer 131 and the second semiconductor layer 133 may be a layer formed of a material, such as gallium nitride (GaN), gallium phosphide (GaP), gallium arsenide phosphide (GaAsP), aluminum gallium indium phosphide (AlGaInP), indium aluminum phosphide (InAIP), aluminum gallium nitride (AlGaN), aluminum indium nitride (AlInN), aluminum indium gallium nitride (AlInGaN), aluminum gallium arsenide (AlGaAs), gallium arsenide (GaAs), etc., doped with an n-type or p-type impurity, but the embodiments of the present specification are not limited thereto. For example, the n-type impurity may be silicon (Si), germanium (Ge), selenium (Se), carbon (C), tellurium (Te), tin (Sn), etc., but the embodiments of the present specification are not limited thereto. For example, the p-type impurity may be magnesium (Mg), zinc (Zn), calcium (Ca), strontium (Sr), barium (Ba), beryllium (Be), etc., but the embodiments of the present specification are not limited thereto.

For example, the first semiconductor layer 131 and the second semiconductor layer 133 may be a nitride semiconductor including an n-type impurity and a nitride semiconductor including a p-type impurity, respectively, but the embodiments of the present specification are not limited thereto. For example, the first semiconductor layer 131 may be a nitride semiconductor including a p-type impurity, and the second semiconductor layer 133 may be a nitride semiconductor including an n-type impurity, but the embodiments of the present specification are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may be formed in one of a single well structure, a multi-well structure, a single quantum well structure, a multi-quantum well (MQW) structure, a quantum dot structure, and a quantum wire structure, but the embodiments of the present specification are not limited thereto. For example, the active layer 132 may be formed of indium gallium nitride (InGaN), gallium nitride (GaN), etc., but the embodiments of the present specification are not limited thereto.

As another example, the active layer 132 may include a MQW structure having a well layer and a barrier layer having a greater band gap than the well layer. For example, the active layer 132 may have an InGaN layer as the well layer and an AlGaN layer as the barrier layer, but the embodiments of the present specification are not limited thereto.

The anode electrode 134 may be disposed between the first semiconductor layer 131 and the solder pattern SDP. For example, the anode electrode 134 may electrically connect the first semiconductor layer 131 to the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material capable of eutectic bonding with the solder pattern SDP, but the embodiments of the present specification are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), an alloy thereof, etc., but the embodiments of the present specification are not limited thereto.

The cathode electrode 135 may be disposed on the second semiconductor layer 133. For example, the cathode electrode 135 may electrically connect the second semiconductor layer 133 to the second electrode CE2. The cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material so that light emitted from the light-emitting element ED may emit upward with respect to the light-emitting element ED, but the embodiments of the present specification are not limited thereto. For example, the cathode electrode 135 may be formed of a material, such as indium tin oxide (ITO), indium zinc oxide (IZO), indium gallium zinc oxide (IGZO), etc., but the embodiments of the present specification are not limited thereto.

The encapsulation film 136 may be disposed on at least parts of the first semiconductor layer 131, the active layer 132, the second semiconductor layer 133, the anode electrode 134, and the cathode electrode 135. For example, the encapsulation film 136 may surround the at least parts of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may surround side surfaces of the first semiconductor layer 131, side surfaces of the active layer 132, and side surfaces of the second semiconductor layer 133.

For example, the encapsulation film 136 may be disposed on at least parts of the anode electrode 134 and the cathode electrode 135, for example, an edge portion (or one side) of the anode electrode 134 and an edge portion (or one side) of the cathode electrode 135. At least a part of the anode electrode 134 may be exposed with respect to the encapsulation film 136 to connect the anode electrode 134 to the solder pattern SDP. For example, at least a part of the cathode electrode 135 may be exposed with respect to the encapsulation film 136 to connect the cathode electrode 135 to the second electrode CE2. For example, the encapsulation film 136 may be formed of an insulation material, such as silicon nitride (SiNx) or silicon oxide (SiOx), but the embodiments of the present specification are not limited thereto.

As another example, the encapsulation film 136 may have a structure in which a reflective material is dispersed in a resin layer, but the embodiments of the present specification are not limited thereto. For example, the encapsulation film 136 may be manufactured to be a reflector having various structures, but the embodiments of the present specification are not limited thereto. Light emitted from the active layer 132 by the encapsulation film 136 may be reflected upward, thereby increasing light extraction efficiency. For example, the encapsulation film 136 may be a reflective layer, but the embodiments of the present specification are not limited thereto.

According to the present disclosure, the light-emitting element ED has been described as having a vertical structure, but the embodiments of the present specification are not limited thereto. For example, the light-emitting element ED may have a lateral structure or a flip chip structure.

The first light-emitting element 130 has been described with reference to FIG. 7, but the second light-emitting element 140 and the third light-emitting element 150 may have substantially the same structure as the first light-emitting element 130. For example, the second light-emitting element 140 and the third light-emitting element 150 may have substantially the same structure as the first semiconductor layer 131, the active layer 132, the second semiconductor layer 133, the anode electrode 134, the cathode electrode 135, and the encapsulation film 136 of the first light-emitting element 130.

According to the present disclosure, a first optical layer 117a surrounding the plurality of light-emitting elements ED may be disposed in the active area AA. For example, the first optical layer 117a may be disposed to cover the plurality of light-emitting elements ED and banks BNK in areas of the plurality of sub-pixels. For example, the first optical layer 117a may cover the bank BNK, a part of the passivation layer 116, and a space between the plurality of light-emitting elements ED. The first optical layer 117a may be disposed between the plurality of light-emitting elements ED and between the plurality of banks BNK included in one pixel PX or may cover the light-emitting elements ED and the banks BNK. For example, the first optical layers 117a may be disposed to extend in a first direction X and spaced apart from each other in a second direction Y. For example, the first optical layer 117a may be disposed to surround side portions of the light-emitting element ED and the bank BNK between the passivation layer 116 and the second electrode CE2, but the embodiments of the present specification are not limited thereto. For example, the first optical layer 117a may be a diffusion layer, a sidewall diffusion layer, etc., but the embodiments of the present specification are not limited thereto.

The first optical layer 117a may include an organic insulation material having fine particles dispersed therein, but the embodiments of the present specification are not limited thereto. For example, the first optical layer 117a may be formed of siloxane having fine metal particles, such as titanium dioxide (TiO2) particles, dispersed therein, but the embodiments of the present specification are not limited thereto. Light from the plurality of light-emitting elements ED may be scattered by the fine particles dispersed in the first optical layer 117a and emitted to the outside of the display device 1000. Accordingly, the first optical layer 117a can increase the extraction efficiency of the light emitted from the plurality of light-emitting elements ED.

For example, the first optical layer 117a may be disposed in each of the plurality of pixels PX or disposed together in some pixels PX disposed in the same row, but the embodiments of the present disclosure are not limited thereto. For example, the first optical layer 117a may be disposed in each of the plurality of pixels PX, or the plurality of pixels PX may share one first optical layer 117a. As another example, each of the plurality of sub-pixels may additionally include the first optical layer 117a, but the embodiments of the present specification are not limited thereto.

According to the present disclosure, a second optical layer 117b may be disposed on the passivation layer 116 in the active area AA. For example, the second optical layer 117b may be disposed to surround the first optical layer 117a. For example, the second optical layer 117b may be in contact with a side surface of the first optical layer 117a. For example, the second optical layer 117b may be disposed in areas between the plurality of pixels PX. However, the embodiments of the present disclosure are not limited thereto. For example, the second optical layer 117b may be a diffusion layer, a diffusion layer window, a window diffusion layer, or the like, but the embodiments of the present specification are not limited thereto.

The second optical layer 117b may be formed of an organic insulation material, but the embodiments of the present disclosure are not limited thereto. The second optical layer 117b may be formed of the same material as the first optical layer 117a, but the embodiments of the present disclosure are not limited thereto. For example, the first optical layer 117a may include fine particles, and the second optical layer 117b may not include fine particles. For example, the second optical layer 117b may be formed of siloxane, but the embodiments of the present disclosure are not limited thereto.

For example, a thickness of the first optical layer 117a may be smaller than a thickness of the second optical layer 117b, but the embodiments of the present disclosure are not limited thereto. Accordingly, in a plan view, an area in which the first optical layer 117a is disposed may include a concave portion recessed inward from an upper surface of the second optical layer 117b.

According to the present disclosure, the second electrode CE2 may be disposed on the first optical layer 117a and the second optical layer 117b. For example, the second electrode CE2 may be electrically connected to a plurality of contact electrodes CCE through contact holes of the second optical layer 117b. For example, the second electrode CE2 may be disposed on the plurality of light-emitting elements ED. For example, the second electrode CE2 may include a transparent conductive oxide, such as indium tin oxide (ITO), indium zinc oxide (IZO), etc., but the embodiments of the present disclosure are not limited thereto. For example, the second electrode CE2 may be disposed in contact with the cathode electrode 135. For example, the second electrode CE2 may overlap the first optical layer 117a. For example, the second electrode CE2 may cover an outer flat surface of the first optical layer 117a,

The second electrode CE2 may extend continuously in the first direction of the substrate 110. Accordingly, the second electrode CE2 may be commonly connected to the plurality of pixels PX disposed in the first direction of the substrate 110. For example, the second electrode CE2 may be commonly connected to the plurality of pixels PX.

According to the present disclosure, the second electrode CE2 may extend continuously on the first optical layer 117a, the second optical layer 117b, and the light-emitting element ED. The area in which the first optical layer 117a is disposed may include the concave portion recessed inward from the upper surface of the second optical layer 117b. Accordingly, a first portion of the second electrode CE2 disposed on the first optical layer 117a may be disposed along the concave portion and thus may be disposed at a lower location than a second portion of the second electrode CE2 disposed on the second optical layer 117b.

A third optical layer 117c may be disposed on the second electrode CE2. The third optical layer 117c may be disposed to overlap the plurality of light-emitting elements ED and the first optical layer 117a. Since the third optical layer 117c is disposed above the second electrode CE2 and the plurality of light-emitting elements ED, it is possible to eliminate spots (mura) that may occur in some of the plurality of light-emitting elements ED. For example, when the plurality of light-emitting elements ED are transferred onto the substrate 110 of the display device 1000, an area of which distances between the plurality of light-emitting elements ED are not uniform may occur due to a process deviation and the like. When the distances between the plurality of light-emitting elements ED are not uniform, a light-emitting area of each of the plurality of light-emitting elements ED may be disposed non-uniformly, thereby making spots (mura) visible to a user. Accordingly, since the third optical layer 117c formed to uniformly diffuse light is formed above the plurality of light-emitting elements ED, it is possible to reduce the light emitted from some light-emitting elements ED from being visible as spots. Accordingly, since the light emitted from the plurality of light-emitting elements ED is uniformly diffused by the third optical layer 117c and extracted to the outside of the display device 1000, it is possible to improve the luminance uniformity of the display device 1000.

The third optical layer 117c may include an organic insulation material having fine particles dispersed therein, but the embodiments of the present specification are not limited thereto. For example, the third optical layer 117c may be formed of siloxane having fine metal particles, such as titanium dioxide (TiO2) particles, dispersed therein, but the embodiments of the present specification are not limited thereto. For example, the third optical layer 117c may be formed of the same material as the first optical layer 117a, but the embodiments of the present specification are not limited thereto. For example, the third optical layer 117c may be a diffusion layer, a sidewall diffusion layer, etc., but the embodiments of the present specification are not limited thereto.

According to the present disclosure, the light from the plurality of light-emitting elements ED may be scattered by the fine particles dispersed in the third optical layer 117c and emitted to the outside of the display device 1000. The third optical layer 117c may uniformly mix the light emitted from the plurality of light-emitting elements ED, thereby further improving the luminance uniformity of the display device 1000. In addition, it is possible to increase the light extraction efficiency of the display device 1000 through the light scattered by the fine particles, thereby enabling low-power driving of the display device 1000.

A black matrix BM may be disposed on the second electrode CE2, the first optical layer 117a, the second optical layer 117b, and the third optical layer 117c in the active area AA. For example, the black matrix BM may fill the contact hole of the second optical layer 117b. Since the black matrix BM is formed to cover the active area AA, it is possible to reduce color mixing of light of a plurality of sub-pixels and external light reflection. For example, since the black matrix BM is also disposed in a contact hole by which the second electrode CE2 and the contact electrode CCE are connected, it is possible to prevent light leakage between neighboring sub-pixels.

For example, the black matrix BM may be formed of an opaque material, but the embodiments of the present disclosure are not limited thereto. For example, the black matrix BM may be an organic insulation material to which a black pigment or black dye is added, but the embodiments of the present disclosure are not limited thereto.

A cover layer 118 may be disposed on the black matrix BM in the active area AA. The cover layer 118 may protect components under the cover layer 118. For example, the cover layer 118 may be formed of an organic insulation material, but the embodiments of the present specification are not limited thereto. For example, the cover layer 118 may be formed of a photoresist, polyimide (PI), or photo acryl-based material, but the embodiments of the present specification are not limited thereto. For example, the cover layer 118 may be an overcoating layer, an insulating layer, etc., but the embodiments of the present specification are not limited thereto.

The polarization layer 293 may be disposed on the cover layer 118 via a first adhesive layer 291. The cover member 120 may be disposed on the polarization layer 293 via a second adhesive layer 295. For example, the first adhesive layer 291 and the second adhesive layer 295 may include an OCA, an OCR, a PSA, etc., but the embodiments of the present specification are not limited thereto.

According to the present disclosure, the plurality of pad electrodes PE may be disposed on the third insulating layer 115c in the second non-active area NA2. For example, at least parts of the plurality of pad electrodes PE may be exposed with respect to the passivation layer 116. For example, the plurality of pad electrodes PE may be electrically connected to the 2-4 connection line 122d through a contact hole of the third insulating layer 115c.

An adhesive layer ACF may be disposed on the plurality of pad electrodes PE. The adhesive layer ACF may be an adhesive layer in which conductive balls are dispersed in an insulation material, but the embodiments of the present specification are not limited thereto. When heat or pressure is applied to the adhesive layer ACF, the conductive balls may be electrically connected at a portion in which the heat or pressure is applied, thereby providing conductive characteristics. The adhesive layer ACF may be disposed between the plurality of pad electrodes PE and the flexible circuit board (or the flexible film) 150 to attach or bond the flexible circuit board (or the flexible film) 150 to the plurality of pad electrodes PE. For example, the adhesive layer ACF may be an anisotropic conductive film (ACF), but the embodiments of the present specification are not limited thereto.

The flexible circuit board (or the flexible film) 150 may be disposed on the adhesive layer ACF. The flexible circuit board (or the flexible film) 150 may be electrically connected to the plurality of pad electrodes PE through the adhesive layer ACF. Accordingly, signals output from the flexible circuit board (or the flexible film) 150 and the printed circuit board may be transmitted to the pixel driving circuit PD of the active area AA through the plurality of pad electrodes PE, the 2-4 connection line 122d, the 2-3 connection line 122c, the 2-2 connection line 122b, and the 2-1 connection line 122a.

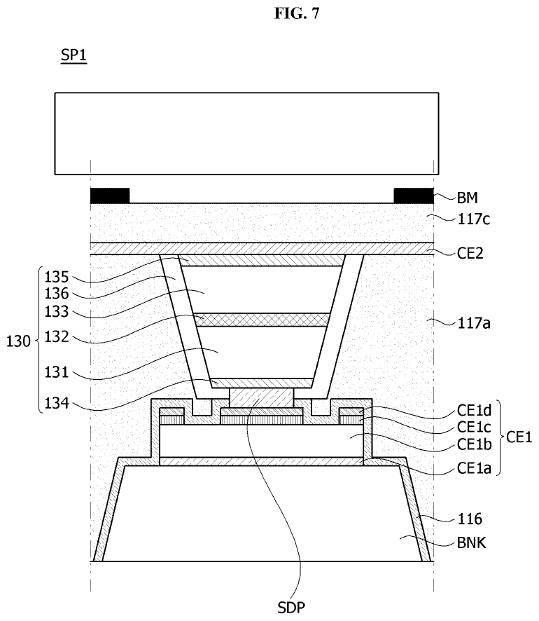

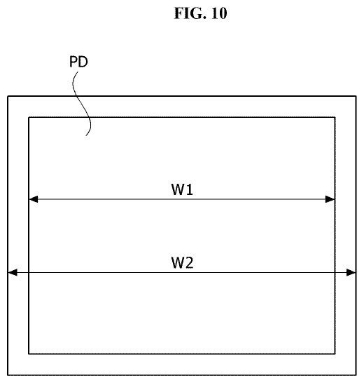

FIGS. 8 to 10 are views illustrating the configuration of a display device according to another embodiment of the present disclosure.

As illustrated in FIG. 8, another embodiment of the present disclosure provides a configuration in which a step is formed in a part of the adhesive layer 112 in which the pixel driving circuit PD is located. The pixel driving circuit PD may be located in the middle of the formed step. The step formed in the part of the adhesive layer 112 may have a rectangular shape and a shape that surrounds the pixel driving circuit PD.

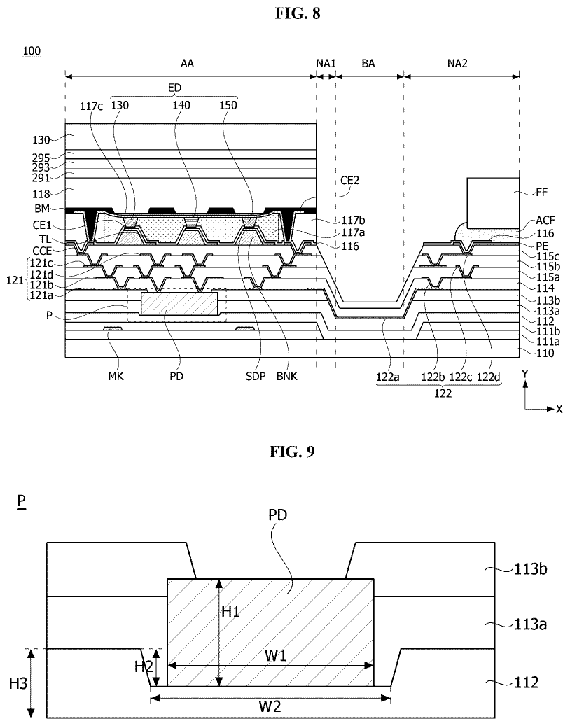

More specifically, as illustrated in FIG. 9, in a cross-sectional structure according to the embodiment of the present disclosure, a width W2 of the step of the adhesive layer 112 may be about 2.5 to 3% greater than a width W1 of the pixel driving circuit PD. A height H2 of the step of the adhesive layer 112 may correspond to a range of about 13% to 16% of a height H1 of the pixel driving circuit PD. The corresponding ranges correspond to design ranges that take into consideration a process tolerance, but the embodiments of the present specification are not limited thereto.

According to an embodiment of the present disclosure, since the pixel driving circuit PD is located in the middle of the step of the adhesive layer 112, a certain area of the step of the adhesive layer 112, in which the pixel driving circuit PD is not located, may be formed. In the corresponding area, the first protective layer 113a may be located in a form that surrounds a part of a lower area of the pixel driving circuit PD. In addition, a part of the second protective layer 113b may be located on the pixel driving circuit PD of which a height has been reduced due to the step of the adhesive layer 112. In this case, a part of the pixel driving circuit PD, which is covered by the part of the second protective layer 113b, may be an edge area of the upper surface of the pixel driving circuit PD. Due to the first protective layer 113a surrounding the part of the lower area of the pixel driving circuit PD and the second protective layer 113b covering the edge of the upper surface of the pixel driving circuit PD, it is possible to increase a fixing force of the pixel driving circuit PD, thereby forming a more solid structure.

In addition, thicknesses of the first protective layer 113a and the second protective layer 113b may be increased by the step of the adhesive layer 112. In addition, the first protective layer 113a and the second protective layer 113b can improve a height deviation of layers according to the transfer of the pixel driving circuit PD, thereby improving flatness of an upper portion thereof. Accordingly, it is possible to increase a transfer rate of the plurality of light-emitting elements and improve product quality.

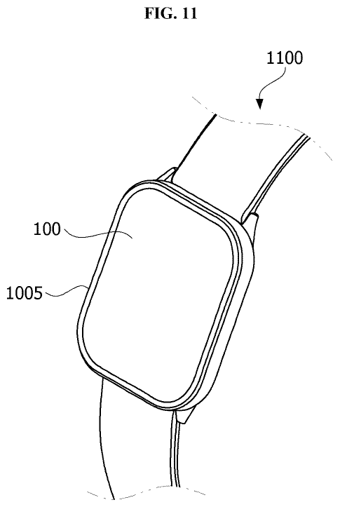

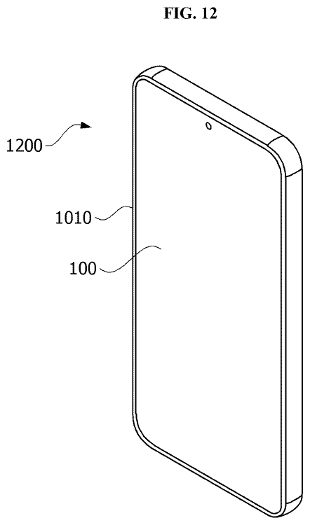

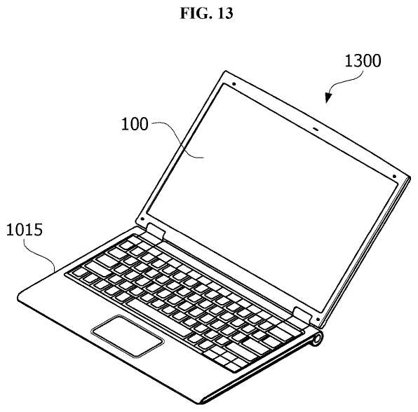

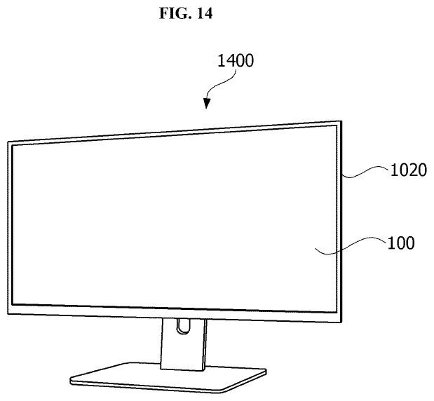

FIGS. 11 to 14 are views illustrating apparatuses to which the display device according to the embodiments of the present specification is applied.

Referring to FIGS. 11 to 14, the display device 1000 according to the embodiments of the present disclosure may be included in various devices or electronic devices. For example, referring to FIGS. 11 to 14, the various electronic devices may include a wearable device 1100, a mobile device 1200, a notebook 1300, and a monitor or TV 1400, but the embodiments of the present specification are not limited thereto.

The wearable device 1100, the mobile device 1200, the notebook 1300, and the monitor or TV 1400 may include case units 1005, 1010, 1015, and 1020, respectively, the display panel 100, and the display device 1000 according to the embodiments of the present disclosure, which are described in FIGS. 1 to 9.

The display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present specification may be applied to an organic light emitting lighting device or an inorganic light emitting lighting device.

According to the present disclosure, it is possible to improve flatness of a pixel driving circuit, thereby increasing a transfer rate of a plurality of light-emitting elements.

In addition, according to the display device according to the embodiments of the present disclosure, a part of an overcoating layer can be disposed on the pixel driving circuit, thereby increasing a fixing force of the pixel driving circuit.

According to the display device according to the embodiments of the present disclosure, it is possible to increase a process rate through the above effects, thereby reducing production energy and maximizing an electrostatic discharge (ESD) effect through the effects, such as high efficiency, a long lifetime, etc.

Effects of the present disclosure are not limited to the above-described effects, and other effects that are not mentioned will be able to be clearly understood by those skilled in the art based on the above detailed description.

The display device according to various embodiments of the present disclosure may be described as follows.

A display device according to one embodiment of the present disclosure may comprise a substrate; one or more buffer layers disposed on the substrate; an adhesive layer disposed on the buffer layer; a pixel driving circuit disposed on the adhesive layer; a protective layer which is disposed on the adhesive layer and of which a part is disposed on the pixel driving circuit; and a plurality of light-emitting elements electrically connected to the pixel driving circuit.

According to one embodiment of the present disclosure, the display device may further comprise a plurality of organic insulation layers disposed on the protective layer.

According to one embodiment of the present disclosure, the display device may further comprise a connection line disposed to overlap the protective layer and some of the plurality of organic insulation layers and electrically connected to the pixel driving circuit.

According to one embodiment of the present disclosure, the plurality of organic insulation layers disposed on the pixel driving circuit may include a protrusion that overlaps a part of the protective layer.

According to one embodiment of the present disclosure, the display device may further comprise an optical layer disposed to surround the plurality of light-emitting elements and formed of an organic insulation material.

According to one embodiment of the present disclosure, the display device may further comprise a plurality of bank patterns that support the plurality of light-emitting elements; a plurality of first electrodes disposed between the plurality of bank patterns and the plurality of light-emitting elements; and a plurality of signal lines that electrically connect the plurality of first electrodes to the pixel driving circuit.

According to one embodiment of the present disclosure, the display device may further comprise a plurality of contact electrodes electrically connected to the pixel driving circuit; and one or more second electrodes disposed on the optical layer and electrically connected to the plurality of contact electrodes.

According to one embodiment of the present disclosure, the display device may further comprise a black matrix disposed on the optical layer and including a plurality of transmissive holes.

According to one embodiment of the present disclosure, the display device may further comprise a scattering agent that scatters light in a part of an internal area of the optical layer.

According to one embodiment of the present disclosure, the display device may further comprise a cover layer disposed on the black matrix.

According to one embodiment of the present disclosure, the adhesive layer may include a step, and the pixel driving circuit is disposed on the step.

According to one embodiment of the present disclosure, a height of the step may be 20% or less of a height of the pixel driving circuit.

According to one embodiment of the present disclosure, the protective layer may include one or more protective layers.

According to one embodiment of the present disclosure, the one or more protective layers may include a first protective layer, a second protective layer, and a third protective layer.

According to one embodiment of the present disclosure, a part of the first protective layer may be located to surround the pixel driving circuit on a step.

According to one embodiment of the present disclosure, a part of the second protective layer may be disposed on the pixel driving circuit.

Although embodiments of the present disclosure have been described in more detail with reference to the accompanying drawings, the present disclosure is not necessarily limited to the embodiments, and various modifications may be carried out without departing from the technical spirit of the present disclosure.

Therefore, the embodiments disclosed in the present disclosure are not intended to limited the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display device comprising:
a substrate;
one or more buffer layers on the substrate;
an adhesive layer on the one or more buffer layers;
a pixel driving circuit on the adhesive layer;
a protective layer on the adhesive layer and of which a part is on the pixel driving circuit; and
a plurality of light-emitting elements electrically connected to the pixel driving circuit.

2. The display device of claim 1, further comprising:
a plurality of organic insulation layers on the protective layer.

3. The display device of claim 2, further comprising:
a connection line overlapping the protective layer and some of the plurality of organic insulation layers, the connection line electrically connected to the pixel driving circuit.

4. The display device of claim 3, wherein the plurality of organic insulation layers on the pixel driving circuit include a protrusion that overlaps a part of the protective layer.

5. The display device of claim 1, further comprising:
an optical layer surrounding the plurality of light-emitting elements, the optical layer including an organic insulation material.

6. The display device of claim 1, further comprising:
a plurality of bank patterns that support the plurality of light-emitting elements;
a plurality of first electrodes between the plurality of bank patterns and the plurality of light-emitting elements; and
a plurality of signal lines that electrically connect the plurality of first electrodes to the pixel driving circuit.

7. The display device of claim 5, further comprising:
a plurality of contact electrodes electrically connected to the pixel driving circuit; and
one or more second electrodes on the optical layer and electrically connected to the plurality of contact electrodes.

8. The display device of claim 5, further comprising:
a black matrix on the optical layer, the black matrix including a plurality of transmissive holes.

9. The display device of claim 5, further comprising:
a scattering agent that scatters light in a part of an internal area of the optical layer.

10. The display device of claim 8, further comprising:
a cover layer on the black matrix.

11. The display device of claim 1, wherein the adhesive layer includes a step and the pixel driving circuit is on the step.

12. The display device of claim 11, wherein a height of the step is 20% or less of a height of the pixel driving circuit.

13. The display device of claim 1, wherein the protective layer includes one or more protective layers.

14. The display device of claim 13, wherein the one or more protective layers include a first protective layer, a second protective layer, and a third protective layer.

15. The display device of claim 14, wherein a part of the first protective layer surrounds the pixel driving circuit on a step.

16. The display device of claim 14, wherein a part of the second protective layer is on the pixel driving circuit.
